(19) United States
(12) Patent Application Publication
(10) Pub. No.: US 2011/0265840 A1
(43) Pub. Date: Nov. 3, 2011

(54) SOLAR PANEL EFFICIENCY ESTIMATOR

(76) Inventor: Moshe Sela, Nes Ziona (IL)

(21) Appl. No.: 12/770,743

(22) Filed: Apr. 30, 2010

(51) Int. Cl. H01L 31/042; G01J 1/42

(52) U.S. Cl. 136/244; 356/218

(57) ABSTRACT

A photovoltaic efficiency estimator, comprising a photovoltaic cell covered by a sunlight-penetrable surface; an illuminator for artificially illuminating said surface; and a controller connected to said photovoltaic cell and to said illuminator, said controller being configured to measure an amount of voltage produced in said photovoltaic cell as a result of the artificial illumination by said illuminator, so as to estimate a decrease in the efficiency of said photovoltaic cell caused by dirt on said surface.

### FIELD

Embodiments of the disclosure relate to the field of solar panel efficiency estimation.

### BACKGROUND

A solar panel (also referred to as a photovoltaic panel) is a device which converts sunlight into an electric voltage. Solar panels are commonly used for producing electricity to power homes, factories and the like. A solar panel usually includes a housing comprising an array of photovoltaic cells. The housing, the top part of which usually being made from glass, protects the photovoltaic cells.

Photovoltaic cells produce voltage by what is often referred to as the “photovoltaic effect”. This effect involves the creation of a voltage (or a corresponding electric current) in a material upon exposure to electromagnetic radiation, such as light.

In the photovoltaic effect, exposure to sufficient radiation causes electrons to move within the material of the photovoltaic cell, resulting in the buildup of a voltage between two electrodes.

Solar panels are naturally installed outdoors, and are therefore exposed to dust, soot and other types of dirt which attaches to the top cover of the panel, blocking some of the sunlight and thus reducing the electricity generated by the panel. H. K. Elminir et al., in an article entitled “Effect of dust on the transparent cover of solar collectors” Energy conversion and Management 47 (2006) 3192-3203, describe an experiment done in order to investigate the influence of dust on the performance of photovoltaic systems. The experimental set up involved 100 glass samples, of the type usually used in solar panels, installed at different tilt and azimuth angles. The transmittance of the glass was evaluated at regular intervals over a period of about seven months and after every thunderstorm in the surrounding area. The results showed that the reduction in glass normal transmittance depends strongly on the dust deposition density in conjunction with tilt angle, as well as on the orientation of the surface with respect to the dominant wind direction. With this consideration, one sees that as the dust deposition density goes from 15.84 to 4.48 g/m², the corresponding transmittance diminishes by 52.54-12.38%, respectively.

European Patent No. 0249031 to Helmut et al. discloses in the inside of a diffusion disc, an optical transmitter and a receiver are directly arranged. When the diffusion disc is clean, the radiation emitted by the transmitter passes almost completely through the diffusion disc. Only a small proportion is reflected at the glass/air interface and impinges on the receiver. This small proportion can be used for continuously checking the operability of the transmitter and of the receiver. If dirt particles are located on the outside of the diffusion disc, light is reflected on these and the proportion of the radiation impinging on the receiver increases. A cleaning system can be triggered. The device is of simple construction and is largely free of interfering influences.

Japanese Patent No. 59150484 to Hidenasa et al. discloses a system for automatic cleaning of solar battery panel. To perform unmanned operation by automatically cleaning a photo receiving surface by a method wherein an automatic valve provided to a cleaning water pipe is opened under the condition that the strength of a detection signal from a photo receiving element is over a fixed value, and then cleaning water is sprayed to the photo receiving surface from a nozzle provided to the pipe.

U.S. Pat. No. 6,429,933 to Jackson discloses method for sensing moisture on the exterior surface of a sheet of glass comprising the steps of positioning an imaging lens in spaced relationship to the interior surface of the sheet of glass, passing light waves from moisture on the exterior surface of the sheet of glass through the imaging lens and producing first and second successive images of the moisture on the glass, and successively directing the first and second images from the lens onto a focal plane detector. The method is characterized by storing the first image, storing the second image, comparing the first and second images, and providing a control signal in response to predetermined differences between the first and second images.

German Patent No. 10137339 to Flothkoetter et al. discloses optical device has a transmitter directing electromagnetic radiation onto the inside of the windscreen at a given angle, with detection of the back reflected electromagnetic radiation by a sensor, receiving radiation at an angle of between 29 and 35 degrees to the normal to the windscreen.

German Patent No. 4102146 to Hurst discloses a dirt sensor for the outside of a windscreen includes a light source a reflection surface and a photo-detector. The latter are located on the inside of the screen, and light from the light source is reflected by a screen/air bordering surface. If the screen becomes dirty or wet, light is decoupled by a primary optical element and is coupled by a secondary optical element. The source and the detector are located to correspond with the appropriate points on a rotational ellipse. At least one of the optical elements is pref. made of an acrylic glass.

German Published Patent Application No. 102005042962 to Himmler et al. discloses A transparent vehicle surface dirt sensor correlates pseudo random periodic transmitted and received infra red signals scattered by the surface or dirt to determine the distance from the correlation maximum position and the contamination level from the maximum height. An external light filter is included.

U.S. Pat. No. 7,245,367 to Miller et al. discloses In accordance with yet another aspect of the present invention, a viewing system comprises: a window for protecting the viewing system from an environment of a scene viewable by the system; an imager disposed behind the window for capturing images of the scene through a viewing area of the window and for converting the images into image data; at least one light source disposed to inject light edgewise into the window to cause reflections of the injected light off of contaminants on the window surface, the imager also for capturing images of the scene including the light reflected from the contaminants; and a processor for processing both of image data of the scene excluding reflected light from the contaminants, and image data of the scene including reflected light from the contaminants to detect the contaminants on the external surface. U.S. Pat. No. 4,321,419 to Hanafin discloses a solar panel cover assembly is provided which includes a supply of film material transparent to radiation utilized by a solar panel. The cover assembly further includes means for positioning a portion of the supply of film material over the solar panel to cover and protect the solar panel, and includes means for moving the film material to present clean film material for covering the solar panel.

U.S. Pat. No. 5,136,750 to Takashima et al. discloses a vacuum cleaner with a rotatable member which is housed in a suction nozzle and which is operated by an electric motor driven by to a power source in response to a closing operation of a first switch, the vacuum cleaner comprising dust sensor means for detecting dust in air drawn through the suction nozzle and adjusting means coupled to the dust sensor means for adjusting the sensitivity of the dust sensor means for the dust detection. The adjusting means includes resistor means and a second switch which are coupled in parallel to each other so that the second switch shorts the resistor means when entering into a closed state, the second switch being coupled to the first switch so as to be operable in accordance with the operation of the first switch.

U.S. Pat. No. 5,644,219 to Kurokawa discloses a solar energy system constructed by connecting, between a photovoltaic source and a load, detecting means for detecting the operating point of the photovoltaic source and power converting means for controlling the power to be supplied to the load based on the detection signal from the detecting means, characterized in that the detecting means connects at least two photovoltaic arrays with approximately the same voltage-current characteristics in parallel, connects current limiting elements of different voltage drops in the forward direction in series to each of the photovoltaic arrays and detects the operating point of the photovoltaic source based on the output signal from each of the current limiting elements.

U.S. Pat. No. 5,693,949 to Paris discloses a second main object of the invention is to provide a device for checking the activity of the dust emitted during melting of irradiated materials in a furnace and taking place in a ventilation duct comprising a light radiation emitter positioned facing a first wall of the duct, a first light radiation detector placed in front of the wall opposite to the first wall of the duct and supplying a signal characteristic of the density of the traversed medium within the duct, at least one second gamma radiation detector positioned facing the duct and supplying a signal characterizing the activity of the traversed medium within the duct and acquisition and processing means connected to the first and second detectors for receiving said characteristic signals.

U.S. Pat. No. 6,291,762 to Jan et al. discloses a photovoltaic module with the advantages of being dustproof and weather resistant, comprising: (a) a front substrate which is a light transmittable safety glass plate, on which a photo-catalyst is applied; (b) a back substrate which is a weather resistant polyester polymer membrane; and (c) a photosensitizer located between the front substrate and the back substrate, which comprises electrical circuit copper foils and polymeric enclosing material (EVA).

U.S. Pat. No. 5,910,700 to Crotzer discloses a dust sensing apparatus which operates by oscillating a transducer substrate located in a sensing environment and determining the dust presence from the dampening effect such dust has on the oscillation frequency. By utilizing a conductive polymer such as poly-vinylidene-fluoride, an inexpensive yet effective sensor can be developed. Such a substrate is treated to provide conductive portions in a particular pattern. Source electrodes are then attached to the non-conductive portions, and ground electrodes connected to the conductive portions. An AC voltage applied to the source electrodes will then create a piezoelectric effect causing substrate to deform. Rapid, alternating deformations caused by the AC voltage produce oscillatory, vibrational movement. This oscillation tends toward an inherent resonant frequency depending on the placement of the electrodes and the substrate material. As dust presence dampens the oscillation frequency, a feedback circuit increases the voltage to drive the oscillation frequency back towards resonance. An output signal from the transducer is proportional to the amount of dust accumulated on the transducer, and also provides the feedback. The constant vibration serves to shake dust off the sensor and prevents cumulative build up, allowing the transducer to restore resonant frequency when the dust presence subsides.

U.S. Published Patent Application No. 2005/233125 to Anderson et al. discloses a laminated glass comprised of at least two layers of transparent glass with adjacent glass layers separated by a transparent solid non-glass interlayer or an air cavity, wherein at least one transparent non-glass interlayer or air cavity contains a device comprised of at least one element selected from the group consisting of solid state lighting, heat sensors, light sensors, pressure sensors, thin film capacitance sensors, photovoltaic cells, thin film batteries, liquid crystal display films, suspended particle device films, and transparent electrical conductors.

U.S. Pat. No. 6,469,291 to Bauer et al. discloses detection of moisture over a wide range of lighting conditions. Another object of Bauer's invention is to detect moisture utilizing a charge integrating semiconductor light sensor. Still another object of the present invention is to detect moisture with less susceptibility to temperature variations. Yet another object is to provide a moisture detector that is inexpensive to produce. A further object is to provide a moisture detector capable of detecting a variety of moisture types.

U.S. Pat. No. 7,518,098 to Mack discloses a transmitter unit and/or a receiver unit comprised of an injection molded part with a radiation transmitter and/or radiation receiver incorporated into it; the test surface is comprised of an exit surface of the transmitter unit and an entrance surface of the receiver unit. This makes it possible not only to detect dirt adhering to the test surface, but also to analyze the volume between the exit test surface and the entrance test surface. This makes it possible, for example, to detect mist or smoke. The injection molded part contains essential optical components of the transmitter unit and/or receiver unit such as reflectors, lenses, and the like, and can be shaped independently of the actual sensor body, which can be limited to a simple carrying function. The optical components, which are integrated into the injection molded part comprising the transmitter unit and/or receiver unit, can already be oriented and adjusted as part of the manufacture of the injection molded part and thus completely independently of the sensor body of the sensor device.

U.S. Pat. No. 7,486,326 to Ito et al. discloses an optical apparatus having dust-off function, comprising: a dust-off filter located in the vicinity of an optical electronic device; and a vibrating mechanism configured to vibrate the dust-off filter, the vibrating mechanism controlling vibrating operation so that the frequency of vibration waves generated in the dust-off filter changes with the passage of time.

U.S. Pat. No. 7,442,119 to Fluhrer discloses a transmitter device constructed for emitting a laser beam. The use of a laser beam is both economically and technically advantageous. Through the emission of virtually parallel laser light by a laser light transmitter, it is possible to obtain a clearly defined intensity relative to the cross-sectional surface of the laser beam. This permits the implementation of longer measurement sections within the ventilator, without a suitable evaluation being made more difficult through an excessive expansion of the light cone. If the laser beam emitted by the transmitter device encounters air contamination such as cooking vapours or fluctuating air density gradients, it is refracted, diffracted, deflected and/or scattered. As a result the power recorded by the receiver device changes compared with the output power of the transmitter device. These power changes, and also the frequency of the power fluctuations, are dependent on the quantity of air contamination and/or the measurement of the air movement on the measurement section.

U.S. Pat. No. 7,280,145 to Takizawa et al. discloses a camera having a dust-proofing member at a predetermined position in front of an image pick-up device, in which the number of members arranged between a photographing optical system and the image pick-up device is reduced, and a high degree of freedom is ensured on optical design of the photographing optical system by reducing the size of a camera main body unit, and particularly, by reducing the dimension in the depth direction of the camera main body unit and by decreasing a flange back. And it is also an object to provide an image pick-up device unit used for the camera.

U.S. Pat. No. 6,911,594 to Mazumder discloses a transparent electromagnetic shield to protect solar arrays and the like from dust deposition. The shield is a panel of clear non-conducting (dielectric) material with an embedded array of linear, parallel electrodes made of either metal wires or conducting transparent strips. The electrodes are connected to a single- or multi-phase AC signal. A multi-phase AC signal is able to produce a travelling electromagnetic wave across the surface of the panel, which is able to sweep dust particles from the surface of the panel. The travelling electromagnetic wave lifts dust particles away from the panel and sweeps them away without using any moving parts. A single-phase AC signal may be effective when a panel is oriented vertically or substantially vertically so that dust particles repelled from the surface of the panel fall by gravity without the need for the travelling electromagnetic wave to sweep the particles away.

U.S. Pat. No. 6,822,766 to Hill et al. discloses an optical scanner which includes a scroll fed transport for propelling a document to be scanned along a paper path including an optical reference surface. A light source illuminates the optical reference surface, or if a document is being propelled along the paper path over the optical reference surface, a scan region on the document. A plurality of photosensors receive light reflected from the optical reference surface or the scan region on the document. A circuit connected to the photosensors generates image data representative of information printed or otherwise formed on the document and adjusts the gains applied to the outputs of selected ones of the photosensors to eliminate streaks in the image data otherwise due to the selected photosensors imaging debris on the optical reference surface.

U.S. Pat. No. 7,333,916 to Warfield et al. discloses a method and apparatus is for monitoring the performance of a solar powered electrical supply for an electrical load wherein the supply comprises an array of photovoltaic cells that are mounted on a building and that have a predetermined performance. In one embodiment, the apparatus comprises: an irradiance sensor for producing a signal representative of solar irradiance; a circuit for deriving a running performance signal by using at least the irradiance signal and a measure of the electrical power supplied to the load from the array; a radio for broadcasting the performance signal; and a portable unit for receiving the performance signal from the radio and for visually displaying the performance of the solar electrical system.

U.S. Published Patent Application No. 2009/266353 to Lee discloses an automatic cleaning system for solar panels which comprises a protection panel for protecting the solar panel, a driving device for providing driving force, a cleaning device arranged on the driving device which is driven by the driving device and thereby cleans the solar panel. The automatic cleaning system for solar panel further comprises a detection device that detects the dirt on the solar panel, determines if the solar panel needs to be cleaned, and instructs the driving device clean the solar panel according to the detection result. A method for automatically cleaning the solar panel utilizing the automatic cleaning system is also disclosed, which comprises: providing an automatically cleaning system for a solar panel; obtaining an environmental intensity of sunlight in the outside environment with an environmental light sensor, obtaining a transmitted intensity of incident sunlight throughout the protection panel with a transmission light sensor, and derive a detection difference value between the environmental intensity and the transmitted intensity; comparing the detection difference value with a predetermined value; if the detection difference value is larger than the predetermined value, the solar panel will be cleaned; if the detection difference value is smaller than the predetermined value, the solar panel will not be cleaned; the driving device sends execution signals to a perfusion device and a driving device so as to the driving device drives a cleaning device to clean the solar panel when the solar panel needs to be cleaned.

U.S. Published Patent Application No. 2007/098407 to Hebrank et al. discloses a low-power UV light-based communication system which allows remote communications systems, such as those including remote control units (e.g., television remote control units), to be wireless and, in some cases, without a battery. Due to the high sensitivity of commercially available UV photodetectors and the high conversion efficiencies and power outputs of currently available UV LEDs, short-range, medium-range, and even long-range UV communication methods and systems consistent with this invention can operate at decreased power levels with increased reliability and safety.

The foregoing examples of the related art and limitations related therewith are intended to be illustrative and not exclusive. Other limitations of the related art will become apparent to those of skill in the art upon a reading of the specification and a study of the figures.

### SUMMARY

The following embodiments and aspects thereof are described and illustrated in conjunction with systems, tools and methods which are meant to be exemplary and illustrative, not limiting in scope.

There is provided, according to an embodiment, a solar panel with an embedded efficiency estimation capability, the solar panel comprising: a photovoltaic cell array; an illuminator for artificially illuminating a dirt-effectible surface of said solar panel; and an efficiency estimation module connected to said illuminator and to at least one cell of said photovoltaic cell array, said module being configured to estimate, based on an amount of artificial illumination received by said at least one cell, the efficiency of said solar panel due to dirt on said surface.

In some embodiments, said illuminator is positioned inside a housing of said solar panel.

In some embodiments, said illuminator is positioned external to a housing of said solar panel.

In some embodiments, said module is further configured to differentiate the artificial illumination from external light, thereby enabling efficiency estimation when external light is present.

In some embodiments, the differentiation is based on identifying voltage resulting from the artificial illumination and voltage resulting from the external light.

In some embodiments, the solar panel further comprises an electrical inverter configured to convert direct voltage (DC) from said solar panel to alternating voltage (AC) suitable for a power grid.

In some embodiments, said electrical inverter further comprises an interface module configured to receive efficiency information from said embedded efficiency estimation module.

In some embodiments, said interface module is further configured to receive, and said embedded efficiency estimation module is further configured to transmit, sunlight level information, to enable solar panel malfunction analysis. In some embodiments, said at least one cell is of a same type as other cells of said photovoltaic cell array.

In some embodiments, the estimation by said efficiency estimation module is indifferent to a change in environmental temperature.

There is further provided, according to an embodiment, a photovoltaic efficiency estimator, comprising: a photovoltaic cell covered by a sunlight-penetrable surface; an illuminator for artificially illuminating said surface; and a controller connected to said photovoltaic cell and to said illuminator, said controller being configured to measure an amount of voltage produced in said photovoltaic cell as a result of the artificial illumination by said illuminator, so as to estimate a decrease in the efficiency of said photovoltaic cell caused by dirt on said surface.

In some embodiments, said illuminator is positioned inside a casing of said estimator.

In some embodiments, said illuminator is positioned external to a casing of said estimator.

In some embodiments, said controller is further configured to differentiate the artificial illumination from external light, thereby enabling efficiency estimation when external light is present.

In some embodiments, the differentiation is based on identifying voltage resulting from the artificial illumination and voltage resulting from the external light.

In some embodiments, the photovoltaic efficiency estimator further comprises an electrical inverter configured to convert direct voltage (DC) from said solar panel to alternating voltage (AC) suitable for a power grid.

In some embodiments, said electrical inverter further comprises an interface module configured to receive efficiency information from said controller.

In some embodiments, said interface module is further configured to receive, and said controller is further configured to transmit, sunlight level information, to enable solar panel malfunction analysis.

In some embodiments, the photovoltaic efficiency estimator further comprises a movable cover controllable by said controller, said movable cover being configured to block sunlight from reaching said at least one cell when said illuminator illuminates the sunlight-penetrable surface.

There is further provided, according to an embodiment, a method for calculating the effect of dirt on the efficiency of a solar panel, the method comprising: artificially illuminating a dirt-effectible surface of the solar panel; receiving, by a photovoltaic cell, at least some of the artificial illumination, respective to an amount of dirt present on the dirt-effectible surface; and calculating a ratio between the artificial illumination and the at least some of the artificial illumination received by the photovoltaic cell, to produce a value indicative of the effect of dirt on the efficiency of the solar panel.

In addition to the exemplary aspects and embodiments described above, further aspects and embodiments will become apparent by reference to the figures and by study of the following detailed description.

### BRIEF DESCRIPTION OF THE FIGURES

Exemplary embodiments are illustrated in referenced figures. Dimensions of components and features shown in the figures are generally chosen for convenience and clarity of presentation and are not necessarily shown to scale. It is intended that the embodiments and figures disclosed herein are to be considered illustrative rather than restrictive. The figures are listed below.

FIG. 1 shows a perspective view of photovoltaic solar system;

FIG. 2 shows a perspective view of a photovoltaic panel with an embedded efficiency estimation module;

FIG. 3 shows an efficiency estimation module;

FIG. 4 shows an exemplary assembly of solar panels; and

FIG. 5 shows an exemplary flow chart of a method for calculating solar panel efficiency.

### DETAILED DESCRIPTION

An aspect of some embodiments relates to a solar panel with an embedded efficiency estimation capability, enabling an understanding of the effect of dirt deposition on the panel's energy production efficiency. A common solar panel typically includes an array of photovoltaic cells connected in series. In an embodiment, an illuminator and an efficiency estimation module are embedded within the panel, and connected to at least one of the panel's cells. The illuminator artificially illuminates a dirt-effectible surface of the solar panel, which is usually its top glass cover. The at least one cell may receive at least some of that artificial illumination, whether directly or as a reflection, wherein the amount of illumination received is indicative of the efficiency reduction the panel suffers due to dirt depositions. The efficiency estimation module is configured to calculate and estimate this efficiency reduction.

A further aspect relates to a standalone efficiency estimator, which may be connected to or otherwise associated with a solar panel system. The efficiency estimator may include one or more photovoltaic cells illuminated by an illuminator, and a controller which estimates the efficiency of the cells according to the amount of illumination received by them.

The term “Alternating Current” (A.C.), as referred to herein, may refer to alternating current or to alternating voltage. The term “Direct Current” (D.C.), as referred to herein, may refer to direct current or to direct voltage.

The term “external light”, as referred to herein, may refer to sunlight and/or to a light source which is external and unrelated to a solar panel, such as various lighting elements and floodlights located in proximity to the panel.

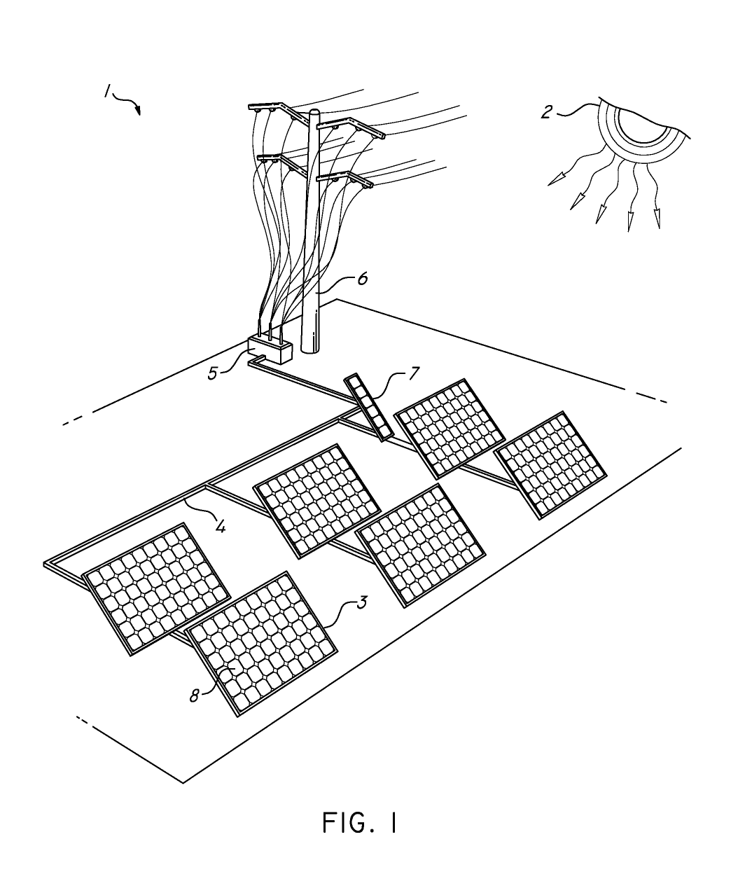

Reference is now made to FIG. 1, which shows an electricity generation system 1. For simplicity of presentation, embedded efficiency estimation is demonstrated with reference to an electricity generation system. Nonetheless, embedded efficiency estimation, according to the present disclosure, may be used in other systems in need for such a capability.

Electricity generation system 1 may include one or more solar panels 3, which generate electric voltage from sunlight 2. The use of multiple solar panels 3 may generate more power from the sun 2. Solar panel 3 may be connected electrically in series. Connecting solar panels 3 in series may yield higher voltages for conversion. Solar panel 3 may include at least one photovoltaic cell such as photovoltaic cell 8 for generating electricity. For simplicity of presentation, solar panel 3 with a rectangular shape is demonstrated. Nonetheless, a solar panel having a different shape may be used. Photovoltaic cell 8 may generate a voltage when exposed to light. The size of each of photovoltaic cell 8 may be a standard size used in the industry, such as 12.5 centimeters by 12.5 centimeters, 15 centimeters by 15 centimeters or the like. Solar panel 3 may have a light-penetrable cover such as glass, plastic and/or the like.

Solar panel 3 may include a cover protecting photovoltaic cells, such as photovoltaic cell 8. While protecting photovoltaic cell 8, the cover may still be light-penetrable, namely, it may allow light to pass through it without great losses. Dirt, such as dust, mud soot and/or the like on the light-penetrable material may affect the passage of light through it. The cover, which may also be referred to as the dirt-effectible surface of solar panel 3, may be made of a material such as glass, plastic and/or the like.

Electricity generation system 1 may include conducting wiring 4. Conducting wiring 4 may deliver the generated electrical power from solar panel 3 to an electric inverter 5. Electric inverter 5 may convert a direct voltage (DC) produced by solar panels 3 into an alternating voltage (AC). Electric inverter 5 may be further equipped and configured to report operation parameters, such as efficiency of solar panel 3, panel malfunction, voltage levels and/or the like, to a remote location. Electric inverter may have an interface module connected to a communication channel (not shown) for sending and/or receiving parameters to/from one or more elements of electricity generation system 1, and optionally for transmitting the parameters out, to a control center, to the owner or operator of the system and/or the like. The communication channel may use any type of wired or wireless links. One example is the use of a serial protocol, such as RS485, over the main electric voltage. Data may be transmitted along with the electricity produced by solar panels 3, over conducting wires 4.

Electric inverter 5 may transfer the electric energy produced by solar panels 3 to the power grid, such as through an electric pole 6, shown only for illustrative reasons.

An efficiency estimator 7 may be used for estimating the efficiency of electricity generation system 1 due to dirt depositions on the covers of solar panels 3. Efficiency estimator 7 is further explained below. Generally, it may be connected to electric wiring 7 and/or have its own wiring which optionally goes to electric inverter 5.

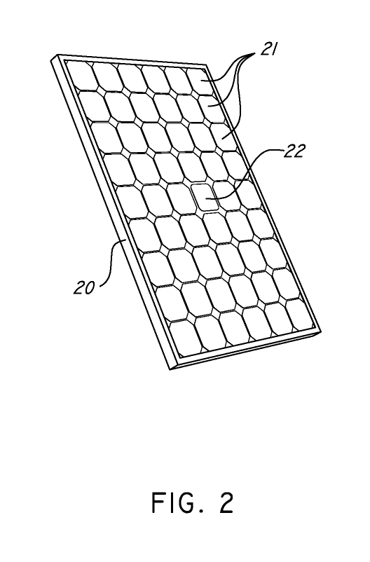

FIG. 2 shows another solar panel 20, having an embedded, built-in, efficiency estimation capability. For simplicity of presentation, a solar panel having a rectangular shape is demonstrated. Nonetheless, a solar panel having a different shape may be used. Solar panel 20 may include at least one photovoltaic cell, such as photovoltaic cells 21. Photovoltaic cells 21 may generate a voltage when exposed to light. The size of each of photovoltaic cells 2 may be, for example, a standard size used in the industry, such as 12.5 centimeters by 12.5 centimeters, 15 centimeters by 15 centimeters or the like. Solar panel 20 may have a light-penetrable cover such as glass, plastic and/or the like.

According to an embodiment, solar panel 20 may include at least one efficiency estimation module 22 (hereinafter “efficiency estimator”) embedded therein. Efficiency estimator 22 may output estimated efficiency of at least one solar panel such as solar panel 20. Efficiency estimator 22 may be placed in any location within solar panel 20. For example, it may be positioned instead of one or more photovoltaic cells of the array. Efficiency estimator module 22 is further explained below. It may include at least one photovoltaic cell, which is optionally of the same type as photovoltaic cells 21, for enhancing accuracy of the estimation. The term “same type” may refer to cells having essentially the same response to light in terms of voltage produced by the same amount of light, cells made of similar materials, cells of the same manufacturing model and/or the like.

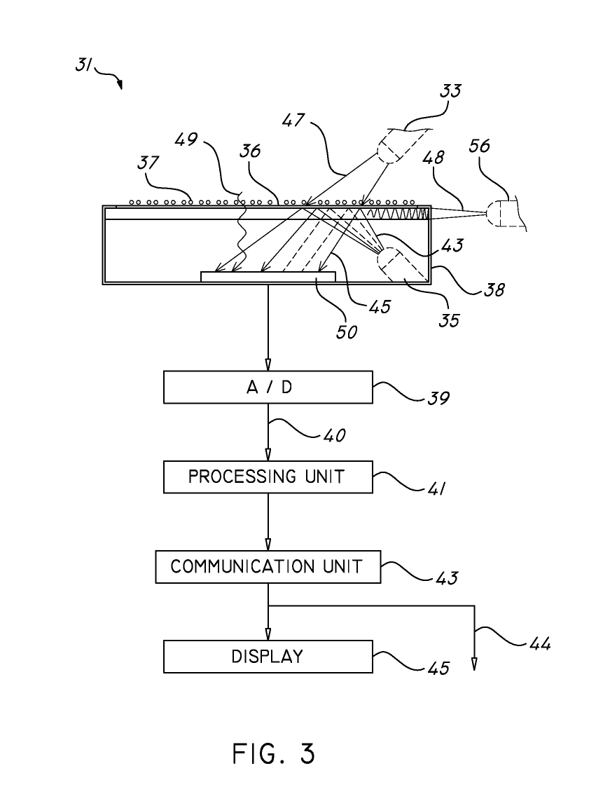

FIG. 3 shows an exemplary efficiency estimator 31 (also referred to as an “efficiency estimator module”) in more detail, in accordance with an embodiment. Efficiency estimator 31 may be a standalone module such as efficiency estimator 7 of FIG. 1, or embedded in a solar panel, as in efficiency estimator 22 of FIG. 2.

A photovoltaic cell, such as photovoltaic cell 50, may be used for light detection. Efficiency estimator module 31 may include at least one photovoltaic cell 50. For simplicity of presentation, one photovoltaic cell is demonstrated within the efficiency estimator module, although more photovoltaic cells may be used. In certain scenarios, more photovoltaic cells may generally help averaging the measurements and may give a more accurate efficiency figure. For example, a dirt deposition of 5 centimeters by 5 centimeters may cover around 11.11% of a 15 cm by 15 cm single photovoltaic cell. Using three photovoltaic cells each having a 15 centimeters by 15 centimeters dimension, the same dirt of 5 centimeters by 5 centimeters may cover only approximately 3.7% of the photovoltaic cells area.

In an embodiment, a photovoltaic cell may be used for efficiency measurement, and, at the same time, be part of the array of power-generating photovoltaic cells of the panel, and contribute to generation of electricity.

In an embodiment, an artificial light source 35 (also referred to as an “illuminator”) may indirectly illuminate photovoltaic cell 50 through reflections from dirt, such as dirt 37, deposited on a top cover of efficiency estimator 31, such as light-penetrable surface 36. Artificial light source 35 may be positioned inside a casing (also “housing”), such as casing 38 of efficiency estimator 31. An artificial light beam 43 emitted from light source 35 may be irradiated angularly towards light-penetrable surface 36. The angle between artificial light beam 43 and light-penetrable surface 36 may be, for example in the range of 0° to 10°, 10° to 20°, 20° to 30°, 30° to 40°, 40° to 50°, 50° to 60°, 60° to 70°, 70° to 80°, 80° to 90°, and/or the like. The focus of light source 35 may be such that the artificial light reflected, such as reflected light 45, may cover a certain area of photovoltaic cell 50, up to the entirety of the cell. Higher coverage may give better accuracy when calculating efficiency estimation.

Light-penetrable surface 36 may be transparent, semi transparent and/or the like. Semi-transparent light-penetrable surface may help decreasing the effect which strong external light might have on efficiency estimation. A high-intensity beam 49 from the sub may, in some scenarios, overpower reflected beam 45 and prevent it from being sufficiently detected in photovoltaic cell 50. If a semi-transparent light-penetrable surface is used, it may reduce the intensity of high-intensity beam 49 down to a level which may not affect efficiency estimation.

Artificial light 35 may be supplied with an alternating voltage (A.C.). Alternate voltage may rapidly turn artificial light source 35 on and off, at a frequency of, for example, tens of Hertz, hundreds of Hertz, thousands of Hertz and/or the like.

With no dirt on light-penetrable surface 36, light beam 43 may pass through the light-penetrable surface 36 and travel to the atmosphere, and therefore no reflections may reach photovoltaic cell 50. If dirt 37 is present on light-penetrable surface 36, it may cause light beam 43 to be reflected back from it towards photovoltaic cell 50, and cause voltage to be generated in the cell, corresponding to the amount of reflected light and hence corresponding to the effect the dirt has on the efficiency of photovoltaic cell 50.

Calculating the efficiency with light source 35 may be done using level sensing of the reflected beam 45. No dirt 37 on light-penetrable surface 36 may yield no reflections, thus may yield no A.C. signal out of photovoltaic cell 50. Dirt 37 on light-penetrable surface 36 may yield reflected beam 45 A.C. signal out of photovoltaic cell 50.

In an embodiment, an artificial light 33 may be placed external to casing 38 of efficiency estimator 31. In this embodiment, lack of dirt will cause essentially the entire amount of light emitted by artificial light 33 to be received by photovoltaic cell 50, while the existence of dirt 37 will cause less light to be received. In an embodiment, an artificial light 56 may be positioned such that it illuminates light-penetrable surface 36 from its cross section, causing internal reflections within the surface's width, with some of the light escaping the width of the surface. In this embodiment, dirt 37 may intensify the escaping of light downwards, towards photovoltaic cell 50.

The voltage generated by photovoltaic cell 50 may be sampled by an Analog to Digital (A/D) converter 39. A/D converter 39 may sample an analog voltage such as the voltage that may be generated in the photovoltaic cell 50 and may convert it into a digital signal such as digital signal 40. A digital signal 40 may be a combination of 0s and 1s that may represent a value. Digital signal 40 may be used by processing unit such as processing unit 41. Processing unit 41 may analyze signal 40 as sampled by the analog to digital block 39.

Processing unit 41 may filter digital signal 40, to detect D.C. and A.C. components in the voltage generated by photovoltaic cell 50. Detected D.C. may be attributed to sunlight, whereas detected A.C. may be attributed to the artificial illumination and/or to other, non-related light sources affecting photovoltaic cell 50, such as external flood lights installed in proximity. The frequency of the A.C. of the artificial lights may be designed to be different and distinguishable from the frequency of the non-related light sources, which is commonly 50 or 60 Hz. Calculation and/or estimation of the efficiency reduction due to dirt, by processing unit 41, may be performed by computing the ratio between the intensity of light outputted by the artificial illuminator and the intensity of artificial light received by photovoltaic cell 50. As a simplistic example, if the artificial illuminator is configured to emit light at an X intensity level, and the voltage generated by photovoltaic cell 50 in response to the illumination is 0.8×, the efficiency reduction due to dirt is 20%.

Notably, since a photovoltaic cell is used for received the artificial illumination, efficiency estimator 31 may be indifferent to change in environmental conditions which generally affect photovoltaic cell, such as temperature, humidity and/or the like. That is, the environmental conditions may affect photovoltaic cell 50 in essentially the same way they affect the power-generating photovoltaic cells used in proximity, and therefore the efficiency estimation by estimator 31 may inherently take into accoun\ these effects and provide a reliable estimation in virtually any condition.

The A/D converter 39 and/or processing unit 41 may be severally or jointly referred to as “controller”.

In an embodiment (not shown), a physical movable cover may be used to temporarily shield photovoltaic cell from sunlight during measurement of light from an artificial light source. The timing of movement of the cover may be controlled by the controller. The physical cover may make A.C. and D.C. differentiation unnecessary, since during measurement, only light from the artificial light source (whether irradiated in A.C. or D.C.) is received by the photovoltaic cell.

Back to FIG. 3, a calculation result such as calculation result 44 may be sent to the electrical inverter. Result 44 may be sent through a wired or wireless communication unit 43, such as RS485, infrared, BlueTooth, radio frequency and/or the like. Result 44 may be used by the inverter for reporting solar panel condition. The inverter may gather all efficiency estimator data for averaging efficiency, panel malfunction and/or the like. The reporting of the electrical inverter may help an operator or an owner of an electricity generation system to know when it is best to clear the solar panels.

In an embodiment, result 44 of the efficiency estimation may signal an automatic cleaning system to start cleaning the solar panels of the electricity generation system. A display, such as display 45, may present efficiency estimation, electricity generated, light level and/or the like to a user. Display 45 may be positioned in or in proximity to efficiency estimator 31, or may be located remotely, either having a direct connection (wired or wireless) to the estimator or an indirect connection, through the inverter.

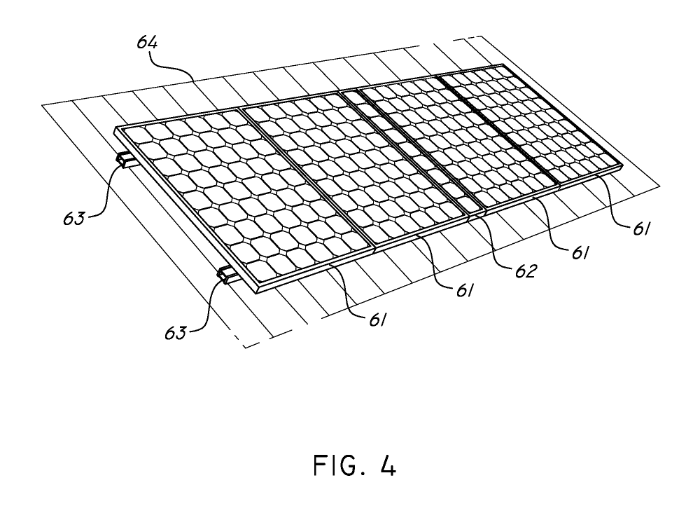

Efficiency estimator 31 may be packed in a standalone case such as case 38. Efficiency estimator may be packed with photovoltaic cells in solar panel case such as efficiency estimator 22 in solar panel 20 in FIG. 2. FIG. 4 shows an installation option for the solar panel and a standalone efficiency estimator module. A solar panel, such as solar panel 61, may be mechanically attached to metal stripes such as metal stripes 63. Metal stripes 63 may be attached to a roof 64 or to a different surface. An efficiency estimator, such as efficiency estimator 62, may be mechanically attached to metal stripes 63. Efficiency estimator 62 may be placed in between solar panels 61. Efficiency estimator 62 placed between solar panels 61 may estimate efficiency of nearby panels. Disturbance to efficiency estimator 62 will likely be similar to disturbance to solar panel 61.

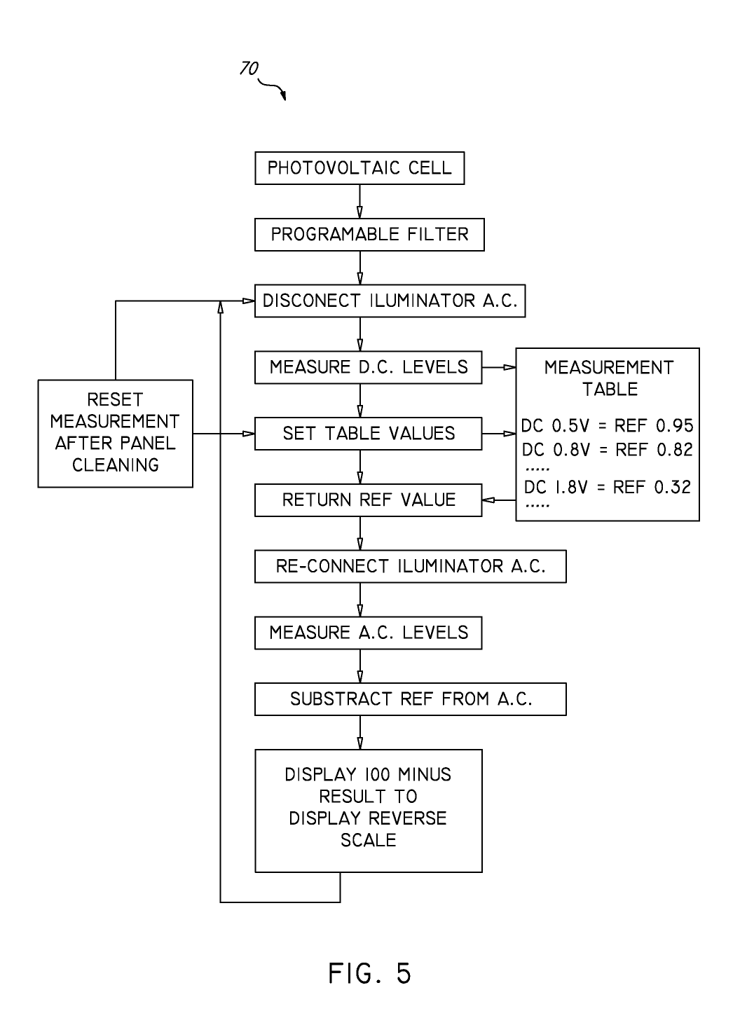

FIG. 5 shows a flow chart of a method 70 for efficiency calculation. Method 70 may be used by the efficiency estimator. Method 70 may include a reset sequence which may take place when the efficiency estimator module is clean of dirt. Method 70 may differentiate between the A.C. level and the D.C. level which may be measured in the photovoltaic cell. The differentiation between the A.C. level and the D.C. level may be done with a programmable filter. This filter may be implemented in software, hardware and/or the like. Method 70 may differentiate between the A.C. level and the D.C. level. The differentiation may help calculating the total light illuminating the efficiency estimator and/or the solar panel. The flow may present the results in any scale such as percentage, light level and/or the like.

While a number of exemplary aspects and embodiments have been discussed above, those of skill in the art will recognize certain modifications, permutations, additions and sub-combinations thereof. It is therefore intended that the following appended claims and claims hereafter introduced be interpreted to include all such modifications, permutations, additions and sub-combinations as are within their true spirit and scope.

In the description and claims of the application, each of the words “comprise” “include” and “have”, and forms thereof, are not necessarily limited to members in a list with which the words may be associated.

What is claimed is:

1. A solar panel with an embedded efficiency estimation capability, the solar panel comprising:
a photovoltaic cell array;
an illuminator for artificially illuminating a dirt-effectible surface of said solar panel; and
an efficiency estimation module connected to said illuminator and to at least one cell of said photovoltaic cell array, said module being configured to estimate, based on an amount of artificial illumination received by said at least one cell, the efficiency of said solar panel due to dirt on said surface.

2. The solar panel according to claim 1, wherein said illuminator is positioned inside a housing of said solar panel.

3. The solar panel according to claim 1, wherein said illuminator is positioned external to a housing of said solar panel.

4. The solar panel according to claim 1, wherein said module is further configured to differentiate the artificial illumination from external light, thereby enabling efficiency estimation when external light is present.

5. The solar panel according to claim 4, wherein the differentiation is based on identifying voltage resulting from the artificial illumination and voltage resulting from the external light.

6. The solar panel according to claim 4, further comprising an electrical inverter configured to convert direct voltage (DC) from said solar panel to alternating voltage (AC) suitable for a power grid.

7. The solar panel according to claim 6, wherein said electrical inverter further comprises an interface module configured to receive efficiency information from said embedded efficiency estimation module.

8. The solar panel according to claim 7, wherein said interface module is further configured to receive, and said embedded efficiency estimation module is further configured to transmit, sunlight level information, to enable solar panel malfunction analysis.

9. The solar panel according to claim 1, wherein said at least one cell is of a same type as other cells of said photovoltaic cell array.

10. The solar panel according to claim 9, wherein the estimation by said efficiency estimation module is indifferent to a change in environmental temperature.

11. A photovoltaic efficiency estimator, comprising:
a photovoltaic cell covered by a sunlight-penetrable surface;
an illuminator for artificially illuminating said surface; and
a controller connected to said photovoltaic cell and to said illuminator, said controller being configured to measure an amount of voltage produced in said photovoltaic cell as a result of the artificial illumination by said illuminator, so as to estimate a decrease in the efficiency of said photovoltaic cell caused by dirt on said surface.

12. The photovoltaic efficiency estimator according to claim 11, wherein said illuminator is positioned inside a casing of said estimator.

13. The photovoltaic efficiency estimator according to claim 11, wherein said illuminator is positioned external to a casing of said estimator.

14. The photovoltaic efficiency estimator according to claim 11, wherein said controller is further configured to differentiate the artificial illumination from external light, thereby enabling efficiency estimation when external light is present.

15. The photovoltaic efficiency estimator according to claim 14, wherein the differentiation is based on identifying voltage resulting from the artificial illumination and voltage resulting from the external light.

16. The photovoltaic efficiency estimator according to claim 14, further comprising an electrical inverter configured to convert direct voltage (DC) from said solar panel to alternating voltage (AC) suitable for a power grid.

17. The photovoltaic efficiency estimator according to claim 16, wherein said electrical inverter further comprises an interface module configured to receive efficiency information from said controller.

18. The photovoltaic efficiency estimator according to claim 17, wherein said interface module is further configured to receive, and said controller is further configured to transmit, sunlight level information, to enable solar panel malfunction analysis.

19. The photovoltaic efficiency estimator according to claim 11, further comprising a movable cover controllable by said controller, said movable cover being configured to block sunlight from reaching said at least one cell when said illuminator illuminates the sunlight-penetrable surface.

20. A method for calculating the effect of dirt on the efficiency of a solar panel, the method comprising:
artificially illuminating a dirt-effectible surface of the solar panel;
receiving, by a photovoltaic cell, at least some of the artificial illumination, respective to an amount of dirt present on the dirt-effectible surface; and
calculating a ratio between the artificial illumination and the at least some of the artificial illumination received by the photovoltaic cell, to produce a value indicative of the effect of dirt on the efficiency of the solar panel.
